(19) United States
(12) Patent Application Publication
(10) Pub. No.: US 2009/0032071 A1
(43) Pub. Date: Feb. 5, 2009

(54) LID FOR A SEMICONDUCTOR DEVICE PROCESSING APPARATUS AND METHODS FOR USING THE SAME

(75) Inventors: Joseph Yudovsky, Campbell, CA (US); Hui Chen, Burlingame, CA (US); Gary Ettinger, Cupertino, CA (US)

Correspondence Address: DUGAN & DUGAN, PC, 245 Saw Mill River Road, Suite 309, Hawthorne, NY, 10532, US

(73) Assignee: Applied Materials, Inc.

(21) Appl. No.: 12/245,742

(22) Filed: Oct. 4, 2008

Related U.S. Application Data
(62) Division of application No. 11/080,361, filed on Mar. 15, 2005.
(60) Provisional application No. 60/553,314, filed on Mar. 15, 2004.

(51) Int. Cl. H01L 21/67

(52) U.S. Cl. 134/104.1; 134/182

(57) ABSTRACT

A lid for a semiconductor device processing apparatus is provided. The lid comprises a cover having an opening and a wall formed around the opening, the wall adapted to prevent fluid present on the lid from entering a body of the processing apparatus through the opening, and one or more cover edges including one or more edge walls; an outer door adapted to prevent fluid from entering the body of the processing apparatus through the opening of the cover, wherein the outer door interfaces with the wall formed around the opening and the one or more edge walls; and an inner door coupled to the outer door and adapted to prevent fluid from exiting the body of the processing apparatus through the opening of the cover. Numerous other aspects are provided.

### CROSS REFERENCE TO RELATED APPLICATIONS

This application is a division of, and claims priority to, United States Non-Provisional patent application Ser. No. 11/080,361, filed Mar. 15, 2005, and titled, “LID FOR A SEMICONDUCTOR DEVICE PROCESSING APPARATUS AND METHODS FOR USING THE SAME” (Attorney Docket No. 9109), which claims priority to U.S. Provisional Patent Application Ser. No. 60/553,314, filed Mar. 15, 2004, and titled, “LID FOR A SEMICONDUCTOR DEVICE PROCESSING APPARATUS” (Attorney Docket No. 9109/L). Both of these patent applications are hereby incorporated by reference herein in their entirety for all purposes.

### FIELD OF THE INVENTION

The present invention relates generally to semiconductor device manufacturing, and more particularly to a lid for a semiconductor device processing apparatus and methods for using the same.

### BACKGROUND OF THE INVENTION

A semiconductor device processing apparatus, such as a substrate device, may include a lid. The lid may prevent fluids, such as chemistries or water (e.g., deionized (DI) water) employed during semiconductor device processing, from entering or escaping the semiconductor device processing apparatus. A conventional lid may include a cover which defines an opening. Further, the lid may include a sliding door which slides over the opening defined by the cover and prevents fluids from entering or escaping from the semiconductor device processing apparatus.

During semiconductor device processing chemistries may contact the cover and sliding door and form a residue on the lid of the processing apparatus. Such a residue may cause the lid to malfunction (e.g., stick) during semiconductor device processing. Further, because the cover typically is of a uniform thickness, the cover may be susceptible to sagging.

### SUMMARY OF THE INVENTION

In a first aspect, an inventive lid for a semiconductor device processing apparatus comprises a cover having an opening and a wall formed around the opening. The wall is adapted to prevent fluid present on the lid from entering a body of the processing apparatus through the opening. An outer door is adapted to prevent fluid from entering the body of the processing apparatus through the opening of the cover, and an inner door, coupled to the outer door, is adapted to prevent fluid from exiting the body of the processing apparatus through the opening of the cover.

In a second aspect, the inventive lid comprises a cover having a top surface, an opening formed therein and a wall formed around the opening and extending upwardly from the top surface. The wall is adapted to prevent fluid present on the top surface of the lid from entering a body of the processing apparatus through the opening. The lid further comprises an outer door coupled so as to slide between a closed position wherein the outer door occludes the opening, and an open position wherein the outer door does not occlude the opening. The outer door is positioned above the top surface of the cover a distance at least equal to a height of the wall.

In a third aspect, the inventive lid comprises a cover having an opening, an outer door adapted to deter fluid from entering a body of the processing apparatus through the opening, and an inner door coupled to the outer door and adapted so as to deter fluid employed within the body of the processing apparatus from contacting the outer door.

In a fourth aspect, the inventive lid comprises a cover having an opening, an outer door adapted to occlude the opening, and a rinsing mechanism adapted to supply fluid to the lid so as to rinse residue therefrom.

In a fifth aspect, a method of reducing sticking of a door of a semiconductor device processing apparatus, comprises providing rinsing fluid to a lid of a semiconductor device processing chamber so as to rinse particulates therefrom, and sliding a door that is operatively coupled to the lid so as to move between a closed position wherein the door occludes an opening formed in the lid, and an open position wherein the door does not occlude the opening.

Other features and aspects of the present invention will become more fully apparent from the following detailed description, the appended claims and the accompanying drawings.

### BRIEF DESCRIPTION OF THE FIGURES

FIG. 1 illustrates an exemplary semiconductor device processing apparatus including a lid in accordance with an embodiment of the present invention.

FIG. 2 is a front view of the exemplary semiconductor device processing apparatus in accordance with an embodiment of the present invention.

FIG. 3 is a front view of the exemplary semiconductor device processing apparatus in accordance with an embodiment of the present invention.

FIG. 4 is a schematic representation of a cover of a lid in accordance with an embodiment of the present invention.

FIG. 5 is a side isometric view of an outer sliding door and an inner sliding door in accordance with an embodiment of the present invention.

FIG. 6 is a cross-sectional side view of the outer door and inner door in accordance with an embodiment of the present invention.

FIG. 7 is a cross-sectional side view of the exemplary semiconductor device processing apparatus including the lid in accordance with an embodiment of the present invention.

FIG. 8 is a top perspective view of the lid in accordance with an embodiment of the present invention.

FIG. 9 is a top perspective view of the lid including a spray bar in accordance with an embodiment of the present invention.

FIG. 10 is a top perspective view of the lid including the spray mechanism in accordance with an embodiment of the present invention with the outer sliding door omitted.

FIG. 11 is a side perspective view of the exemplary semiconductor device processing apparatus in accordance with an embodiment of the present invention.

FIG. 12 is a top view of an exemplary semiconductor device processing system in accordance with an embodiment of the present invention.

FIG. 13 is a side view of an exemplary semiconductor device processing system in accordance with an embodiment of the present invention.

FIG. 14 is a back view of an exemplary semiconductor device processing system in accordance with an embodiment of the present invention.

### DETAILED DESCRIPTION

Embodiments of the present invention relate to reducing errors during semiconductor device processing caused by lid malfunction (e.g., sticking). The present invention also reduces the occurrence of deformities in the lid, such as cover sagging. Further, the lid of the present invention may be mounted so as to be easily removable from the semiconductor device processing apparatus.

In order to achieve such advantages, an inventive lid comprising a cover having an opening formed therein may comprise (1) a wall surrounding the opening and adapted to prevent fluid present on the lid from entering the opening; (2) an outer door coupled to the lid so as to slide between an open and a closed position, wherein when the door is in the open position a distance at least equal to the height of the wall exists between the top of the cover and the outer door, such that the outer door may not contact residue that may accumulate on the top of the cover, and may thus avoid sticking; (3) a door comprising an outer door and an inner door, wherein the inner door may deter fluids employed within a processing chamber from contacting the outer door, and thereby may deter residue from accumulating thereon and promoting sticking; and/or (4) a rinsing mechanism adapted to rinse residue from a top surface of the cover. Other aspects may include a wall located on the outer door and adapted to deter fluid output from the rinsing mechanism from entering the opening when the outer door is in an open position, additional walls located along one or more of the cover edges and adapted to direct fluid therealong, and/or to provide structural rigidity. Other features may also be included, as described fully below with reference to the figures.

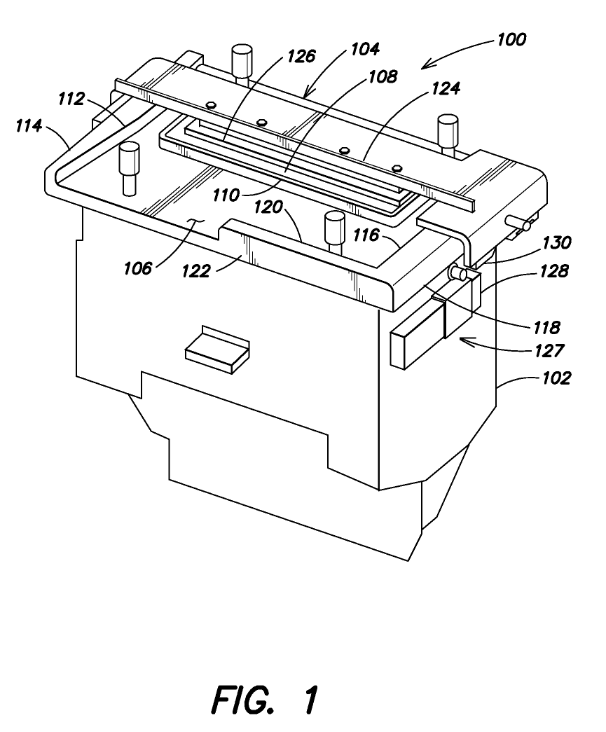

FIG. 1 illustrates an exemplary semiconductor device processing apparatus 100 including a lid in accordance with an embodiment of the present invention. The semiconductor device processing apparatus 100 may be, for example, a megasonic tank, scrubber chamber, spin-rinse-drier chamber or the like. An exemplary scrubber is described in U.S. Pat. No. 6,299,698, an exemplary megasonic cleaner is described in U.S. Pat. No. 6,119,708, and an exemplary spin-rinse-drier chamber is described in U.S. Pat. No. 6,516,816, each of which is incorporated herein in its entirety.

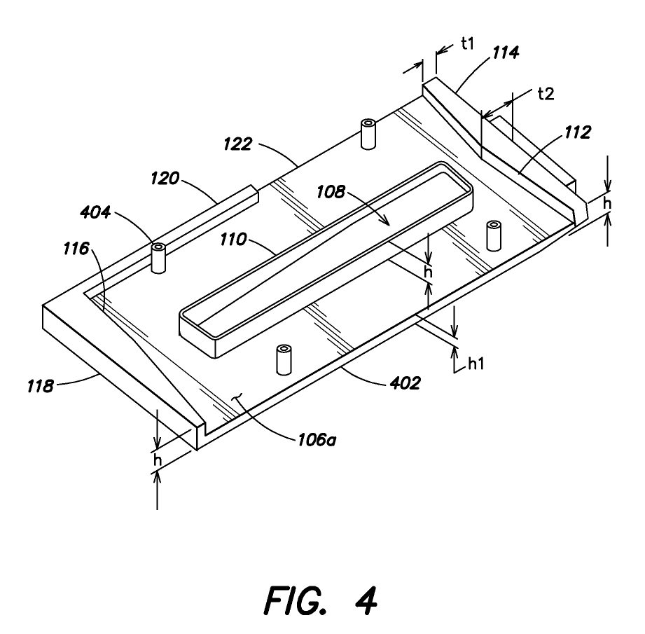

The semiconductor device processing apparatus 100 may include a body (or tank, such as a cleaner module tank) 102 for receiving semiconductor wafers during semiconductor device manufacturing or processing. A lid 104 is coupled to the body 102 and may prevent fluids employed during semiconductor device manufacturing or processing, such as Hydrofluoric acid (HF), Ammonium Hydroxide, Acetic acid, Citric acid and/or DI water, from entering into or escaping from the body 102 of the semiconductor device processing apparatus 100. More specifically, the lid 104 includes a cover 106, which defines an opening 108 through which a semiconductor wafer may be inserted or removed from the semiconductor device processing apparatus 100, for example, by a robot. The cover 106 includes a first wall 110 around the opening 108. The first wall 110 prevents fluid present on the lid 104 from entering the body 102. The cover 106 may include a wall along one or more portions of one or more cover edges. For example, the cover 106 may include a second wall 112 along a first cover edge 114, a third wall 116 along a second cover edge 118, and a fourth wall 120 along a portion of a third cover edge 122. The walls 110, 112, 116, 120 guide fluids present on the cover 106. The details of the cover 106 will be described below with reference to FIG. 4.

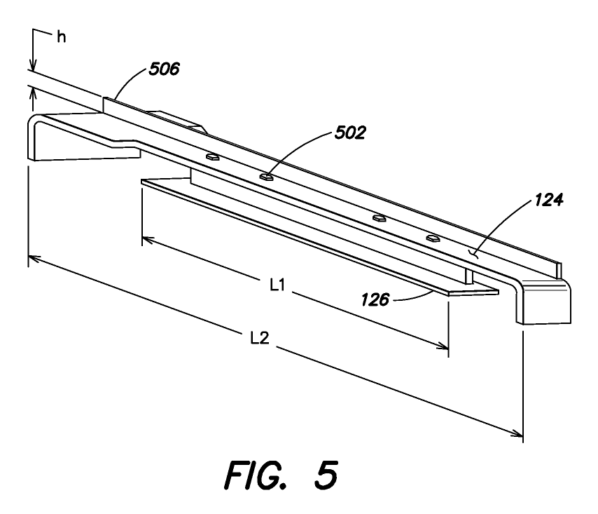

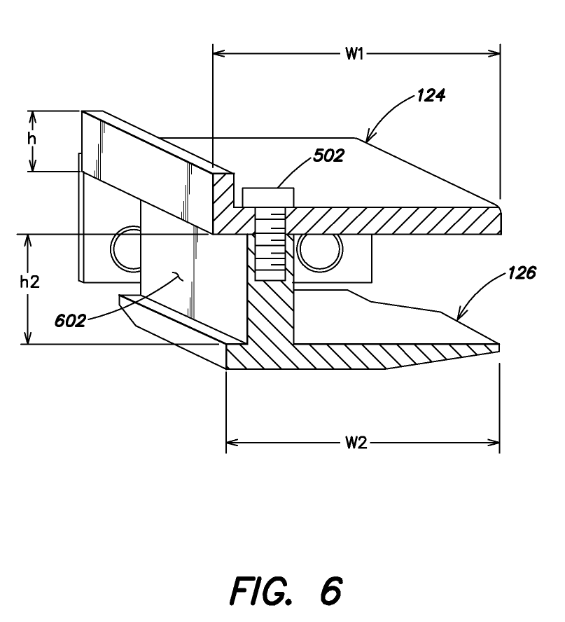

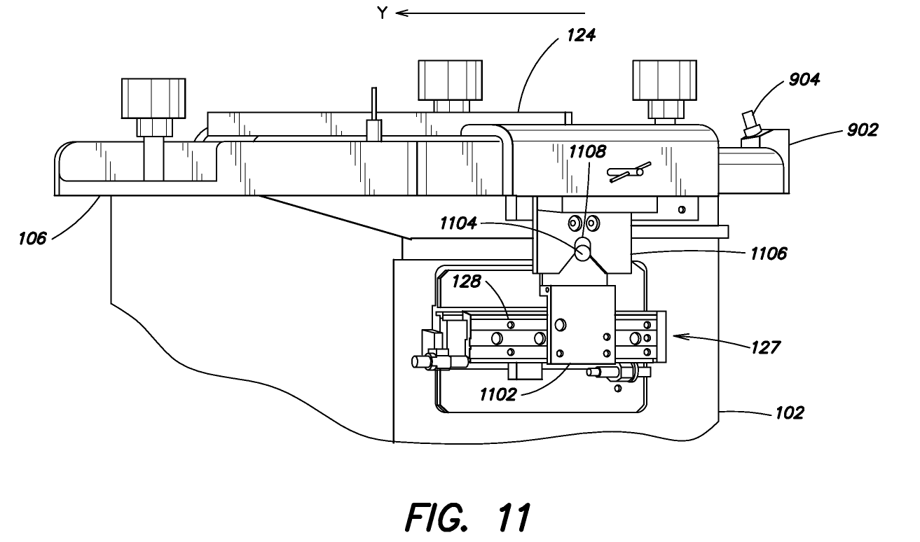

With reference to FIG. 1, the lid 104 includes an outer door 124 coupled to an inner door 126 for preventing fluids from entering and exiting, respectively, the body 102. The outer door 124 (e.g., outer sliding door) and the inner door 126 (e.g., inner sliding door) are movably coupled to the cover 106. More specifically, the outer door 124 is coupled, via an outer door mount 130 to a driving mechanism 127. The driving mechanism 127 may include, for example, a cylinder 128 coupled to the body 102 of the semiconductor device processing apparatus 100 that drives the outer door 124 such that the outer door 124 slides (e.g., in a y-axis direction) along an upper surface of the cover 106. The inner door 126 may move with the outer door 124. The inner door 126 slides along a lower surface of the cover 106. The outer 124 and inner doors 126 are described in detail below with reference to FIGS. 5-6 and the driving mechanism 127 is described in detail below with reference to FIG. 11.

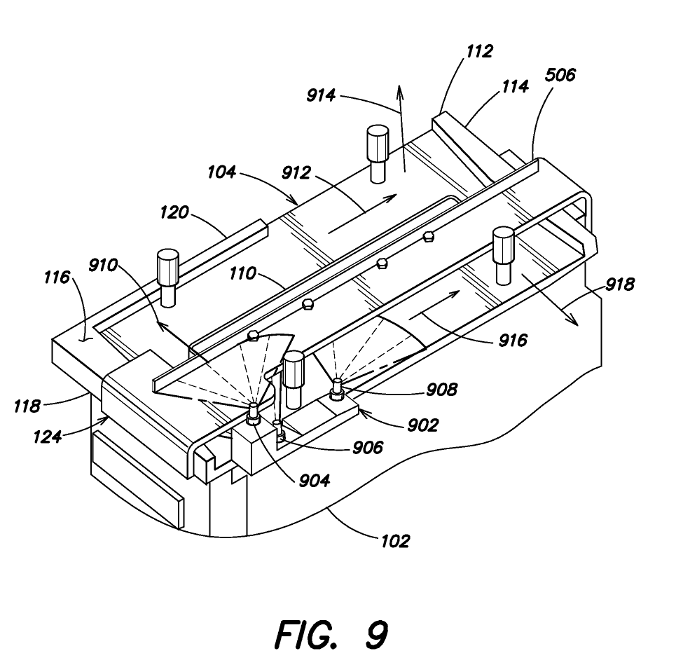

The lid 104 may include a rinsing mechanism (not shown in FIG. 1; reference numeral 902 in FIG. 9) for supplying fluid such as DI water or the like onto the lid 104. The rinsing mechanism 902 may spray additional and/or different fluids onto the lid 104. The fluid may be used to remove any residue formed by chemistries deposited on the lid 104 during semiconductor device processing.

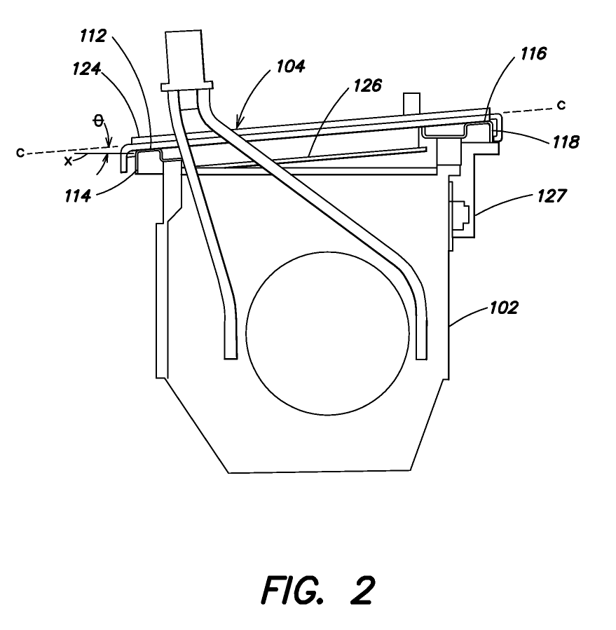

FIG. 2 is a front view of the exemplary semiconductor device processing apparatus 100 in accordance with an embodiment of the present invention. With reference to FIG. 2, the lid 104 is sloped when installed on the body 102 of the semiconductor device processing apparatus 100. More specifically, the lid 104 is sloped along a longitudinal axis c-c of the lid 104, such that the longitudinal axis c-c of the lid 104 forms an angle θ with a horizontal axis (e.g., x-axis). In one embodiment, the longitudinal axis c-c of the lid 104 forms a 5 degree angle with the x-axis. The longitudinal axis c-c of the lid 104 may form a larger or smaller angle with the x-axis. The largest tilt angle allowed by a given design configuration may be desired because such an angle may provide the best fluid drainage. For example, the portion of the lid 104 including the first cover edge 114 is lower than the portion of the lid 104 including the second cover edge 118. Therefore, any fluid present on the lid 104 during semiconductor device processing will travel (e.g., drain) toward the first cover edge 114.

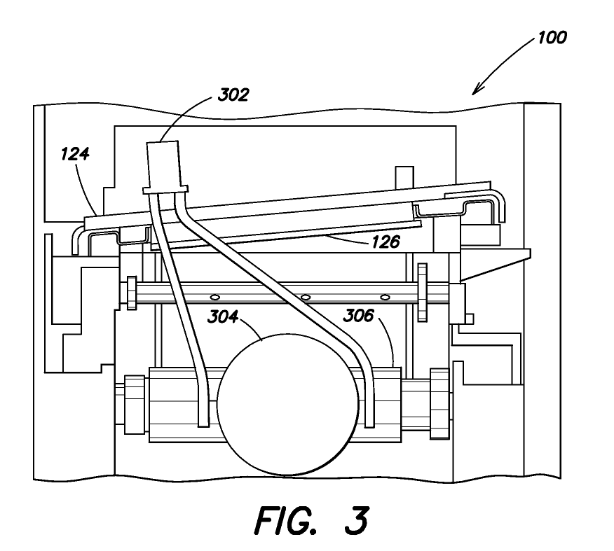

FIG. 3 is a front schematic representation of the exemplary semiconductor device processing apparatus 100 in accordance with an embodiment of the present invention. With reference to FIG. 3, a robot 302 may insert a semiconductor wafer 304 into and/or remove the semiconductor wafer 304 from the semiconductor device processing apparatus 100. The exemplary semiconductor device processing apparatus 100 of FIG. 3 is a brush box, which includes a brush assembly 306. However, the apparatus 100 may be a different type of semiconductor device processing apparatus.

FIG. 4 is a top isometric view of the cover 106 of the lid 104 in accordance with an embodiment of the present invention. With reference to FIG. 4, a major area 106a of the cover 106 is of a first height h1. The first height h1 may be selected based on such factors as strength of the material employed for the cover 106, dimensions of the body 102, etc. As stated, the cover 106 may include a first through fourth wall 110, 112, 116, 120. The walls 110, 112, 116, 120 are preferably as high as a material and/or a space for a design configuration allow. Smaller heights may be used. Further, two or more of the walls 110, 112, 116, 120 may be different heights. The walls 110, 112, 116, 120 increase the material height of the cover 106 thereby increasing the stiffness of the cover 106, and therefore, the lid 104. In this manner, lid deformation (e.g., cover sagging) may be reduced and/or prevented.

As stated above, due to the slope of the lid 104, fluid provided on the lid 104 will flow (e.g., drain) toward the first cover edge 114. Therefore, the fluid may contact the second wall 112. The second wall 112 is shaped such that fluid contacting the second wall 112 will drain from the third cover edge 122 or a fourth cover edge 402. More specifically, the thickness t1 of the center of the second wall 112 is greater than the thickness t2 of the far ends of the second wall 112. The thicknesses t1, t2 may be selected to provide a sufficient angle to allow for adequate fluid drainage (e.g., about 5 degrees or more relative to the cover edge 114, although other values may be used). A similar design may be employed to make the thickness of the center of the third wall greater than the thickness of a far end of the third wall (e.g., the end of the third wall 116 nearest the fourth cover edge 402). In this manner, fluid provided on the cover flows (e.g., drains) toward the first cover edge 114 and may flow from the lid 104 via areas of the third cover edge which do not include a wall and/or the fourth cover edge 402. The fourth wall 120 on a portion of the third cover edge 122 prevents fluid from draining from that portion of the third cover edge 122, and guides the fluid toward the first cover edge 114. As stated the first cover wall 110 prevents the fluid from flowing into the body 102 of the semiconductor device processing apparatus 100 (assuming the opening 108 is covered by the outer door 124 or the fluid level is not higher than the first wall 110 while the opening 108 is not covered).

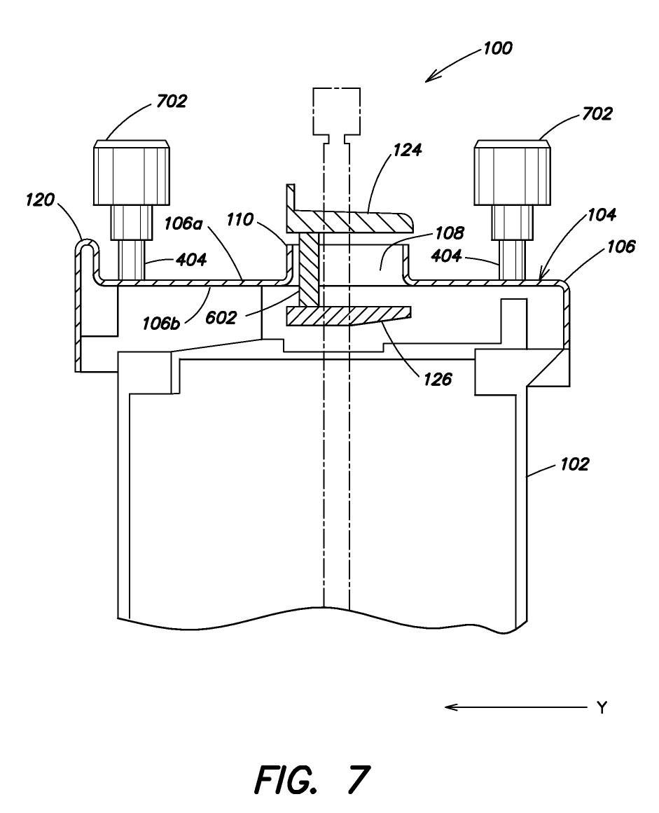

One or more posts 404 may be coupled to the cover 106. The posts 404 are adapted to receive screws and screw bolts (not shown in FIG. 4; 702 in FIG. 7-11) and secure the lid 104 to the body 102. The posts 404 may be coupled to the cover 106 by bonding or similar connection means. In this manner, fluid provided onto the cover 106 is prevented from leaking into the body 102 of the semiconductor device processing apparatus 100 via the points at which the lid 104 is secured to the body 102. In the embodiment shown, the cover 106 includes four posts 404. The cover 106 may include a larger or smaller number of posts 404.

In at least one embodiment, the cover 106 may be formed from chlorinated polyvinyl chloride (CPVC). CPVC is generally compatible (e.g., will not react) with fluids employed during semiconductor device processing. Further, CPVC is compliant with federal semiconductor industry safety standards. The cover 106 may be formed from additional and/or different materials.

FIG. 5 is a side isometric view of an outer sliding door 124 and an inner sliding door 126 in accordance with an embodiment of the present invention. With reference to FIG. 5, the outer door 124 is coupled to (e.g., mounted above) the inner door 126 via one or more bolts 502 or similar connection means. The outer door 124 includes an outer door wall 506 for preventing fluid provided on the lid 104 from entering into the body 102 of the semiconductor device processing apparatus 100. The outer door wall 506 guides the fluid away from the opening 108. The outer door wall 506 may be the same height h as one or more of the walls 110, 112, 116, 120 of the cover 106 (FIG. 1). Alternatively, the outer door wall 506 may be a different height.

Similar to the cover 106, the outer door 124 and inner door 126 may be formed from CPVC. Alternatively, the outer door 124 and inner door 126 may be formed from additional and/or different materials. For example, during semiconductor processing, the inner door 126 of the lid 104 may be exposed to a high-temperature environment (e.g., if a megasonic tank is employed). In such circumstances, the inner door 126 of the lid 104 may include Raydel r-ppsu or a similar material, which is stable in a high-temperature environment.

FIG. 6 is a cross-sectional side view of the outer door 124 and inner door 126 in accordance with an embodiment of the present invention. With reference to FIG. 6, the outer door 124 is adapted to cover (e.g., seal) the opening 108 defined by the first cover wall 110, thereby preventing fluid from entering into the body 102 of the semiconductor device processing apparatus 100. For example, the outer door 124 prevents chemistries from another processing tank from dripping into the body 102 while a robot is transferring a semiconductor wafer 304 to the semiconductor processing apparatus 100. More specifically, the outer door 124 has a length l1 and a width w1 such that the outer door 124 may cover the opening 108 along a top surface (106a in FIG. 7) of the cover 106.

Similarly, the inner door 126 is adapted to cover the opening 108 defined by the first cover wall 110 along a bottom surface (106b in FIG. 7) of the cover 106, thereby preventing fluid from exiting (e.g., spraying out of) the body 102 of the semiconductor device processing apparatus 100. The inner door 126 has a length l2 and a width w2 such that the inner door 126 may cover the opening 108 along the bottom surface (106b in FIG. 7) of the cover 106. Further, the inner door 126 may include a coupling portion 602 of height h2 through which the inner door 126 is coupled to the outer door 124. Therefore, portions of the inner door 126 are separated from the outer door 124 by the height h2. The height h2 is selected such that the outer door 124 may move (e.g., slide) relative to the top surface 106a of the cover 106 and the inner door 126 may move relative to the bottom surface 106b of the cover 106.

FIG. 7 is a cross-sectional side view of the exemplary semiconductor device processing apparatus 100 including the lid 104 in accordance with an embodiment of the present invention. With reference to FIG. 7, when the outer door 124 and inner door 126 are coupled to the cover 106 to form the lid 104, the outer door 124 is above the first cover wall 110 and the inner door is below the bottom surface 106b of the cover 106. In this manner, the outer door 124 may move relative to the top surface 106a of the cover 106 and the inner door 126 may move relative to the bottom surface 106b of the cover 106.

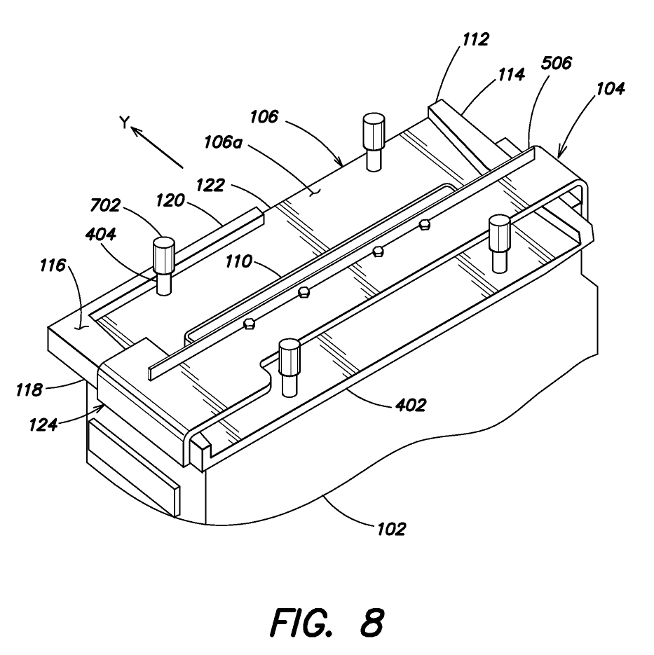

FIG. 8 is a top perspective view of the lid 104 in accordance with an embodiment of the present invention. With reference to FIG. 8, when the outer door 124 is coupled to the cover 106 to form the lid 104, a bottom surface of the outer door 124 may contact the first 110, second 112 and third walls 116. In the embodiment shown, the outer door 124 does not contact other portions of the cover 106. Therefore, in contrast to conventional doors, when the outer door 124 moves relative to the cover 106, the bottom surface of the outer door 124 may contact only the top surfaces of the first cover wall 110, second cover wall 112 and third cover walls 116 and not a larger portion (e.g., all) of the flat surface of the cover 106. Therefore, the present invention reduces the interface (e.g., potential contact area) between the outer door 124 and the cover 106.

FIG. 9 is a top perspective view of the lid 104 including a rinsing mechanism in accordance with an embodiment of the present invention. With reference to FIG. 9, the lid 104 includes a rinsing mechanism 902 (e.g., such as a spray nozzle, a fluid outlet for supplying a fluid drip or flow, a spray bar, etc.) for providing fluid for rinsing the lid (e.g., a cleaning solution, DI water, etc.). In the embodiment shown, the rinsing mechanism 902 is coupled to a side of the cover 106. For example, the rinsing mechanism 902 may be positioned along a side of the cover 106 near the fourth cover edge 402. The rinsing mechanism 902 may be positioned differently.

The exemplary rinsing mechanism 902 includes a plurality of nozzles 904-908 for spraying fluid onto the lid 104. A first nozzle 904 sprays fluid onto the outer door 124. A second nozzle 906 sprays fluid onto a first portion of the cover 106 (e.g., a portion near the second cover edge 118. A third nozzle 908 sprays fluid onto or toward a second portion of the cover 106 (e.g., toward the first cover edge 114). Other numbers of spray bars 902 and/or nozzles may be employed. Through use of the rinsing mechanism 902, residues, which result from the drying of fluid (e.g., chemistries) deposited on the lid 104 during semiconductor device processing, may be removed from the lid 104 before the residues interfere with the movement of the outer door 124 relative to the cover 106. The fluid provided by the rinsing mechanism 902 onto the lid 402 will flow (e.g., drain) in the direction indicated by the arrows 910-918. As shown in FIG. 9, the rinsing mechanism 902 may provide fluid onto the lid 104 (e.g., the outer door 124 and/or the cover 106) while the opening 108 is uncovered. The opening 108 is uncovered, for example, while a wafer is being transferred into and/or out of the body 102 of the semiconductor device processing apparatus 100. The outer door wall 506 and/or the first wall 110 prevents the fluid provided onto the lid 104 by the rinsing mechanism 902 from entering the body 102 of the semiconductor device processing apparatus 100 through the opening 108. Alternatively, the rinsing mechanism 902 may provide fluid onto the lid 104 (e.g., the outer door 124 and/or the cover 106) while the opening 108 is covered. The fluid provided onto the lid 104 by the rinsing mechanism 902 is prevented from entering the body 102 of the semiconductor device processing apparatus 100 in a similar manner. In at least one embodiment, a user may specify when the rinsing mechanism 902 provides fluid onto the lid 104 (e.g., while the opening 108 is covered or uncovered or both). The rinsing mechanism 902 may be hardware or software controlled.

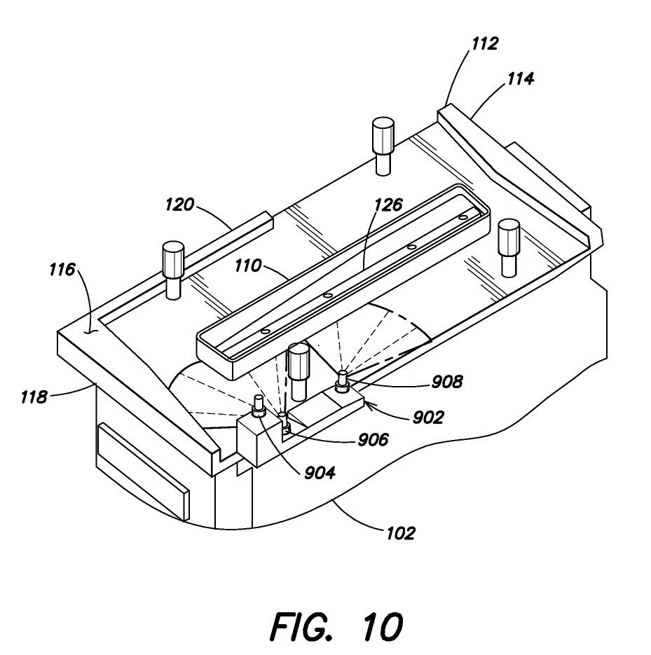

FIG. 10 is a top view of the lid 104 including the rinsing mechanism 902 in accordance with an embodiment of the present invention with the outer door 124 omitted. With reference to FIG. 10, an exemplary range of spray from the second nozzle 906 is clearly illustrated. Further, FIG. 10 illustrates how the first wall 110 prevents fluid from the nozzles 906-908 from entering into the opening 108 by interfering with the spray range of the nozzles 906-908.

FIG. 11 is a side perspective view of the exemplary semiconductor device processing apparatus 100 in accordance with an embodiment of the present invention. With reference to FIG. 11, the driving mechanism 127 is shown coupled to the body 102 (e.g., a side of the body 102) of the semiconductor device processing apparatus 100. The driving mechanism 127 may include a moving bracket 1102 coupled to the cylinder 128. The cylinder 128 may be, for example, an air (e.g., pneumatically actuated) cylinder, and may be controlled by hardware or software. Other driving mechanisms, such as motors and/or lead screws, also may be used. The moving bracket 1102 may include a driving pin 1104 adapted to couple to an outer door bracket (or mount) 1106.

The outer door 124 may be coupled to the outer door bracket (or mount) 1106. For example, the outer door 124 may be coupled to the outer door bracket 1106 via screws or similar connection means. The outer door bracket 1106 is adapted to couple to the driving pin 1104. More specifically, the outer door bracket 1106 may include a notch 1108 for receiving the driving pin 1104. Because the outer door 124 may be coupled to the driving mechanism 127 via the outer door bracket 1106, the outer door 124 may be easily installed or removed (e.g., for servicing) from the semiconductor device processing apparatus 100. Because the lid 104 (e.g., cover 106 and outer door 124) does not require numerous connections to be disconnected before removing the lid 104 and reconnected after installing the lid 104, the lid 104 may be easier to remove and/or install than conventional lids.

In operation, the cylinder 128 causes the moving bracket 1102 to move along the y-axis. The moving bracket 1102 causes the outer door bracket 1106 to move along the y-axis, and consequently, the outer door 124 moves along the y-axis. In this manner, the outer door 124, and therefore, the inner door 126, may move together (e.g., along the y-axis) relative to the cover 106, and cover and/or uncover the opening 108. The outer door 124 may prevent fluid from entering into the body 102 of the semiconductor device processing apparatus 100 through the opening 108 and the inner door 126 may prevent fluid from exiting the body 102 of the semiconductor device processing apparatus 100 through the opening 108. As described above, the interface (e.g., potential contact area) between the outer door 124 and the cover 106 of the lid 104 is reduced compared to conventional lids thereby reducing chances of and/or preventing the outer door 124 from sticking to the cover 106. Further, fluid may be sprayed on and drained from the lid 104 (while the opening 108 is covered or uncovered), thereby cleaning chemistries and/or chemistry residues from the lid 104. Such cleaning does not require removal of the lid 104. Further, the cleaning may be performed before, during and/or after semiconductor device processing.

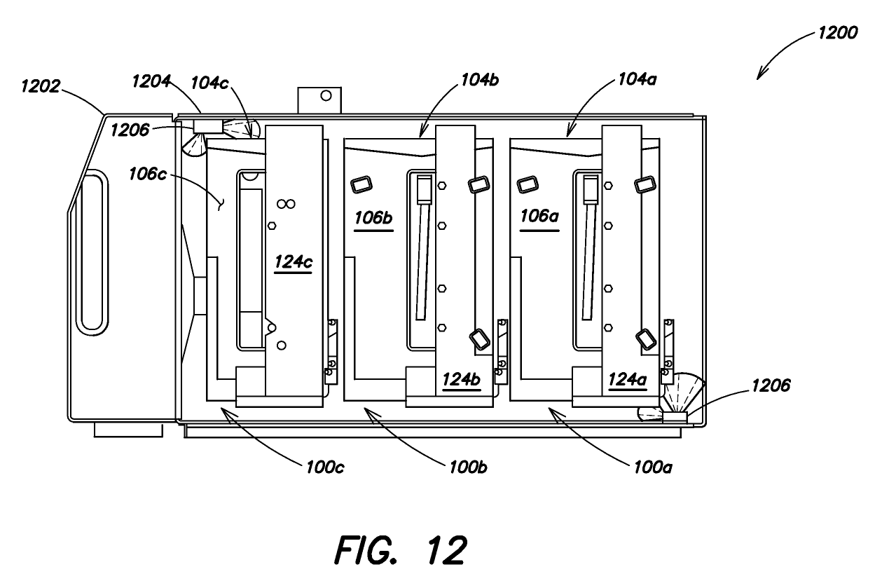

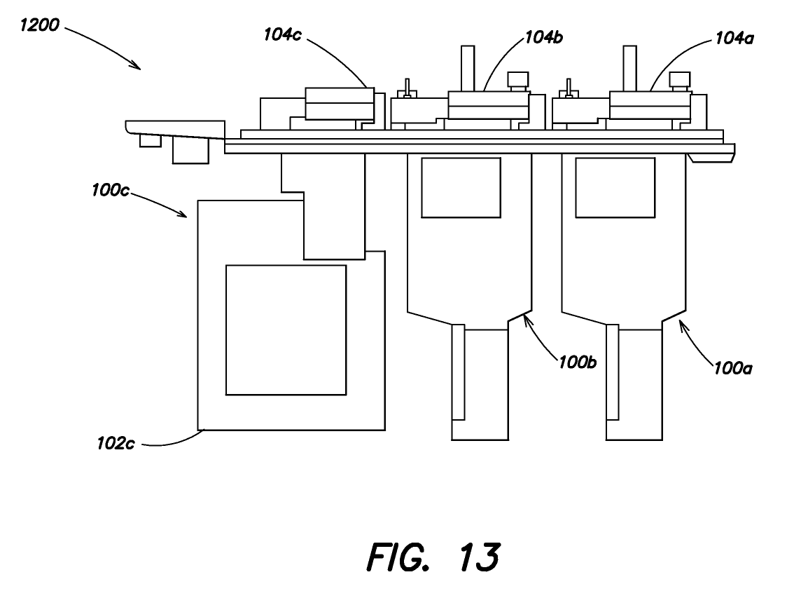

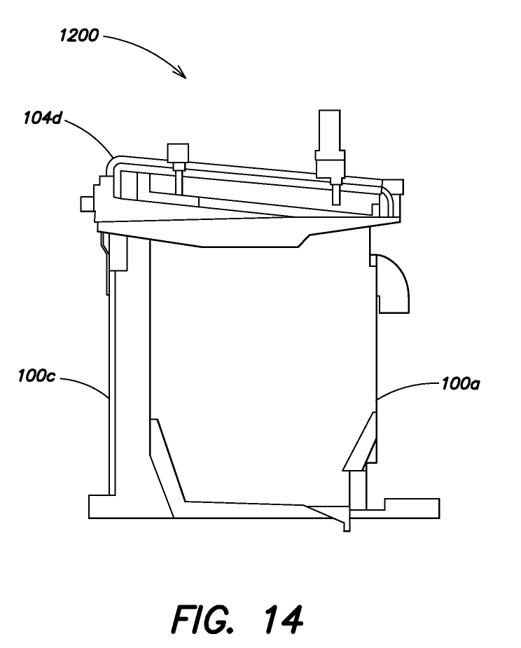

FIGS. 12-14 are a top, side and back view, respectively, of an exemplary semiconductor device processing system 1200 in accordance with an embodiment of the present invention. With reference to FIGS. 12-14, the exemplary semiconductor device processing system 1200 includes an input station 1202 for receiving semiconductor wafers coupled to a plurality of semiconductor device processing apparatus 100a-c (each of which includes a lid 104 in accordance with an embodiment of the present invention). However, a smaller number of semiconductor device processing apparatus may be employed. In one embodiment, the exemplary semiconductor device processing system 1200 may include three semiconductor device processing apparatuses 100. For example, the exemplary semiconductor device processing system 1200 may include a first brush box 100a which includes a first lid 104a in accordance with an embodiment of the present invention and a second brush box 100b which includes a second lid 104b in accordance with an embodiment of the present invention. Further, the exemplary semiconductor device processing system 1200 includes a megasonic cleaner 100c which includes a megasonic tank 102c and a lid 104c similar to the lid 104 described above. The exemplary semiconductor device processing system 1200 includes a drip pan 1204 coupled to the semiconductor device processing apparatus 100a-c. The drip pan 1204 may receive fluids drained from the semiconductor device processing apparatus 100 during semiconductor device processing. The exemplary semiconductor device processing system 1200 includes one or more spray mechanism 1206 for providing fluid, such as cleaning fluid, to the drip pan 1204. In this manner, the drip pan 1204 of the exemplary semiconductor device processing system 1200 is cleaned.

The lids 104a-c of the exemplary semiconductor device processing system 1200 provide the advantages described above, and therefore, increase operating efficiency and manufacturing yield of the system.

The foregoing description discloses only exemplary embodiments of the invention. Modifications of the above disclosed apparatus and methods which fall within the scope of the invention will be readily apparent to those of ordinary skill in the art. For instance, although in some embodiments, the outer door 124 interfaces with the wall 110 formed around the opening 108 and respective walls 112, 116, 120 along portions of one or more cover edges as the outer door 124 slides along the cover 106, thereby reducing a contact area between the outer door and the cover, in other embodiments, the outer door 124 may interface with a larger or smaller area of remaining portions of the lid 104.

Accordingly, while the present invention has been disclosed in connection with exemplary embodiments thereof, it should be understood that other embodiments may fall within the spirit and scope of the invention, as defined by the following claims.

The invention claimed is:

1. A lid for a semiconductor device processing apparatus, comprising:
a cover having an opening and a wall formed around the opening, the wall adapted to prevent fluid present on the lid from entering a body of the processing apparatus through the opening, and one or more cover edges including one or more edge walls;
an outer door adapted to prevent fluid from entering the body of the processing apparatus through the opening of the cover, wherein the outer door interfaces with the wall formed around the opening and the one or more edge walls; and
an inner door coupled to the outer door and adapted to prevent fluid from exiting the body of the processing apparatus through the opening of the cover.

2. The lid of claim 1 wherein the one or more edge walls extend along at least a portion of the one or more cover edges.

3. The lid of claim 2 wherein the outer door interfaces with the wall formed around the opening and the one or more edge walls as the outer door slides between an open and a closed position, thereby reducing a contact area between the outer door and the cover.

4. The lid of claim 3 wherein the one or more edge walls are adapted to guide fluid from a top surface of the cover.

5. The lid of claim 3 wherein the wall formed around the opening or the one or more edge walls increases a thickness of the cover, thereby reducing cover sagging.

6. The lid of claim 1 wherein the inner door and the outer door are moveably coupled to the cover.

7. The lid of claim 6 wherein the inner door further includes a coupling portion, adapted to couple the inner door to the outer door.

8. The lid of claim 6 wherein the outer door is above the wall and the inner door is below a bottom surface of the cover.

9. The lid of claim 8 wherein the outer door is adapted to move relative to a top surface of the cover and the inner door is adapted to move relative to the bottom surface of the cover.

10. The lid of claim 1 further comprising a rinsing mechanism adapted to supply a fluid onto the lid.

11. The lid of claim 10 wherein the rinsing mechanism is adapted to supply the fluid onto the lid at least one of when the opening is covered and uncovered.

12. The lid of claim 1 wherein two or more of the edge walls may be different heights.

13. The lid of claim 1 wherein the lid comprises a first, second, third and fourth edge wall, wherein the first and second edge walls oppose eachother and the third and fourth edge walls oppose eachother.

14. The lid of claim 13 wherein a thickness of at least one of a center of the second and third edge wall is greater than a thickness of each of a far end of the second and third edge wall.

15. The lid of claim 1 wherein the outer door includes an outer door wall.

16. The lid of claim 14 wherein the outer door wall is adapted to prevent fluid on the lid from entering the body of the processing unit.

17. The lid of claim 15 wherein the outer door wall is adapted to guide the fluid away from the opening.

18. The lid of claim 1 wherein the outer door has a length and a width, whereby the outer door covers the opening along a top surface of the cover.

19. The lid of claim 1 wherein the inner door has a length and a width, whereby the inner door covers the opening along a bottom surface of the cover.

20. The lid of claim 13 wherein a bottom surface of the outer door contacts the wall and the first and second edge walls.
